(19) United States
(12) Patent Application Publication
(10) Pub. No.: US 2007/0090527 A1
(43) Pub. Date: Apr. 26, 2007

(54) Integrated chip device in a package

(76) Inventors: Jochen Thomas, Munchen (DE); Steffen Kroehnert, Dresden (DE); Wolfgang Hetzel, Nattheim (DE); Werner Reiss, Bad Feilnbach (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/241,097

(22) Filed: Sep. 30, 2005

(51) Int. Cl. H01L 23/48

(52) U.S. Cl. 257/737

(57) ABSTRACT

The present invention relates to an integrated chip device in a package, including an integrated chip, a substrate comprising a redistribution wiring, a contact element and a contact pad on a common surface of the substrate, wherein the contact element is in electrical contact with the contact pad, wherein the substrate is divided in at least two parts each of which is securely attached to a respective portion of the chip to form the device, wherein between at least two of the parts of the substrate a gap is provided to accommodate a thermal expansion of at least one of the parts of the substrate, a bond wire which is provided to connect the contact pad and the further contact pad of the substrate with the integrated chip through the gap.

### BACKGROUND OF THE INVENTION

1. Field of the Invention

The present invention relates to an integrated chip device in a package, particularly to an integrated chip device comprising a substrate and a chip which is arranged on the substrate.

2. Description of the Related Art

A Bond-channel-type BGA package is a BGA package which includes a substrate and an integrated circuit chip attached thereon. In the substrate a through via slit is provided. The integrated circuit chip has bond pads wherein the chip is arranged such that its bond pads are accessible through the through-via-slit so that bond wires can be led through the through-via-slit to contact the bond pads. The bond wire is led from the bond pads of the integrated circuit chip to respective contact pads arranged on a same surface of the substrate on which contact elements, e.g. solder balls, for externally connecting the BGA device are provided.

One issue of Bond-channel-type BGA device is the thermal expansion mismatch of the substrate and the integrated circuit chip. Thus, a mechanical stress may be induced in the whole BGA device as a result of a temperature change. Due to their larger distance from the package center, a high amount of stress is induced at the outer solder balls in the corners of the BGA device. In a current design of the bond channel type BGA device, the package corners are mechanically connected to the substrate around the bond channel. This results in complex warping forms and leads to high mechanical stress on the solder balls which will lead to sooner failure in board level stress tests.

From the document U.S. Pat. No. 6,288,445 B1, the provision of a BGA device including an integrated circuit chip on a substrate is known. The substrate has a number of separated portions so that each of the portions can expand independently when high temperatures are applied and in such a way that the integrated circuit chip is merely exposed to a reduced mechanical stress. The proposed device refers to a standard BGA device having a substrate on a first side of which contact elements are provided which are connected to contact structures on an opposing surface of the substrate. The electrical connection between the contact structures and the contact elements is realized by a rewiring structure, preferably arranged within the substrate. The rewiring structure is also sensitive to thermal stress and particularly to a bending of the substrate due to different thermal expansion coefficients of the substrate and the integrated circuit chip applied thereon.

### SUMMARY OF THE INVENTION

It is an object of the present invention to provide an integrated chip device, in particular a bond channel type integrated chip device in which the mechanical stress due to heat exposure can be reduced.

According to a first aspect of the present invention, an integrated chip device in a package is provided. The integrated chip device comprises an integrated chip, a substrate comprising a redistribution wiring, a contact element and a contact pad on a common surface of the substrate, wherein the contact element is in electrical contact with the contact pad. The substrate is divided up into at least two parts each of which is securely attached to a respective portion of the chip to form the integrated chip device. Between at least two of the parts of the substrate, a gap is provided to adjust a thermal expansion of at least one of the parts of the substrate. A bond wire is provided to connect the contact pad of the substrate to the integrated chip through the gap.

The integrated chip device of the present invention is a bond channel-type device which comprises a bond channel through the substrate in order to connect the contact elements for externally connecting the integrated chip device with the integrated circuit chip through the bond channel. Thereby, no rewiring structure within the substrate is required. The mechanical stress caused by thermal exposure of the integrated chip device can be reduced in accordance with the present invention providing the substrate in a number of separated portions wherein the gap between two portions of the substrate is used to accommodate an adjustment of the thermal expansion of at least one of the portions of the substrate and to provide the bond channel in which the bond wire for connecting the integrated chip is provided. Thereby, it can simultaneously be achieved that the mechanical stress on the substrate due to thermal exposure is reduced and a bond channel is provided which is necessary to form a bond channel type integrated device package.

According to a preferred embodiment of the present invention, a further contact pad is arranged on the chip which is accessible through the gap between the portions of the substrate.

The gap may comprise a first portion and a second portion wherein the first portion of the gap has a first width which is sufficient to adjust the thermal expansion of at least one of the parts of the substrate and wherein the second portion of the gap has a second width which is sufficient to enable a bonding through the gap onto the further contact pad of the chip.

The chip may be attached to the parts of the substrate by means of at least one of an adhesive and a connection element.

According to another aspect of the present invention, an integrated chip device in a package is provided. The integrated chip devices comprises an integrated chip and a substrate comprising a redistribution wiring, a contact element and a contact pad on a common surface of the substrate, wherein the contact element is in electrical contact with the contact pad. The substrate is divided up into at least two parts each of which is securely attached to a respective portion of the chip to form the device. Furthermore, a bridge element is provided which may be integrally formed by the substrate and by which the at least two parts of the substrate are interconnected. A bond wire which is provided to connect the con-tact pad and the integrated chip through the gap.

The bridge element serves to connect the parts of the substrate in such a way that the handling of the substrate in a fabrication process is easier than the handling of separated parts of the substrate.

The chip may be arranged on the parts of the substrate so that a neutral point of the chip is located on the bridge element of the substrate, wherein the neutral point is defined as the point on which no lateral thermal expansion force occurs when the chip is attached to the parts of the substrate. On the neutral point, the thermal expansions of the different portions of the chip and the respective parts of the substrate compensate each other in such a way that no (lateral) thermal expansion force occurs at this point. Thereby, the bridge element can be rendered small simply in order to connect the number of parts of the substrate to allow an easier handling of the substrate in a fabrication process.

A further contact pad may be arranged on a surface of the chip wherein the chip is mounted on the substrate such that the further contact pad is accessible through the gap between the parts of the substrate. Furthermore, the gap may be provided having a first portion and a second portion wherein the first portion of the gap has a first width which is sufficient to adjust the thermal expansion of at least one of the parts of the substrate and wherein the second portion of the gap has a second width which is sufficient to enable a bonding through the gap onto the further contact pad.

Preferably, the chip is attached to the parts of the substrate by means of at least one of an adhesive and a connection element.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a top view on a substrate of a bond channel type BGA package having a bond channel according to the prior art;

FIG. 2 shows a top view of a substrate for a bond channel type BGA device according to a preferred embodiment of the present invention;

FIG. 3 shows a cross-sectional view through the bond channel type BGA device of FIG. 2 along the line A-A;

FIG. 4 shows a cross-sectional view of the bond channel type BGA device according to the embodiment of FIG. 2 along the line B-B; and

FIG. 5 shows a top view on a substrate according to another preferred embodiment of the present invention.

### DETAILED DESCRIPTION OF THE PREFERRED EMBODIMENT

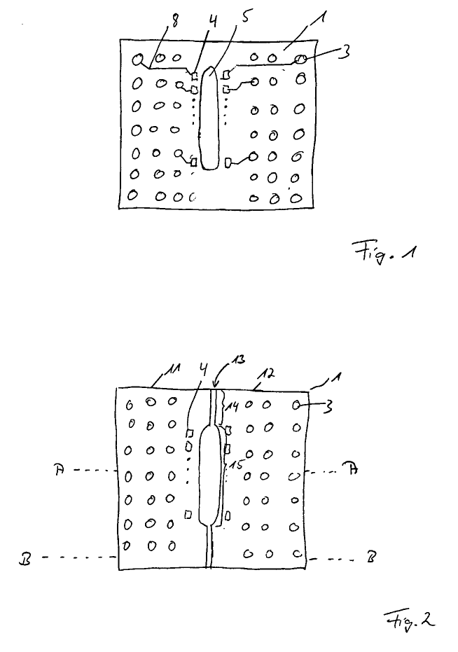

FIG. 1 shows a top view of a substrate 1 for use in a Bond-channel-type BGA device. The Bond-channel-type BGA device comprises the substrate 1 and an integrated circuit chip (not shown) which may be attached on the substrate 1. On one surface, the substrate comprises contact elements 3, e.g. solder balls, and first bond pads 4 each of which are in electrical contact to respective contact elements 3 via a respective connection line 8. Within the substrate 1, a bond channel 5 is formed which is provided as a through-via through the substrate 1. The bond pads 4 are preferably arranged on one or both long sides of the bond channel 5 so that bond wires (not shown) can be led through the bond channel 5 and to the bond pads 4.

If an integrated circuit chip is attached to the substrate, commonly by using an adhesive, glue and/or a mechanical connection which fixates the chip on the substrate 1 by its corners, the Bond-channel-type BGA device undergoes mechanical stress if exposed to a heating. Such a heating occurs while operating the chip or as a result of a heating process which is commonly used after finishing the Bond-channel-type BGA device in order to carry out stress tests such as a Burn-in test board assembly and such like. The mechanical stress is a result of different thermal expansion coefficients of the integrated circuit chip which is usually made of a semiconductor material and the material of the substrate 1 which is normally made of a epoxy resin, ceramic and the like wherein the thermal expansion coefficient of the substrate 1 is usually higher than the thermal expansion coefficient of the semiconductor.

According to one embodiment of the present invention, in order to reduce the mechanical stress in the BGA device, it is proposed to divide up the substrate into two parts 11, 12 as shown in FIG. 2. Same reference signs indicate elements having the same or a similar functionality. The two parts 11, 12 are completely separated from each other. The two parts 11, 12 of the substrate are distanced from one another by two long sides of a gap 13 which has at least one second portion 15 which forms a bond channel and two first portions 14 which have a width sufficient to adjust the expansions of the parts of the substrate due to thermal conditions to which the BGA device is exposed. Preferably, the width of the first portions correspond at least the change of length (i.e., the gap size defined by the distance between the two parts 11, 12) when a maximum temperature is applied (e.g., in a Burn-in test). The bond channel has a width which is sufficient to perform a bonding process through the bond channel in which bond wires are led through the bond channel.

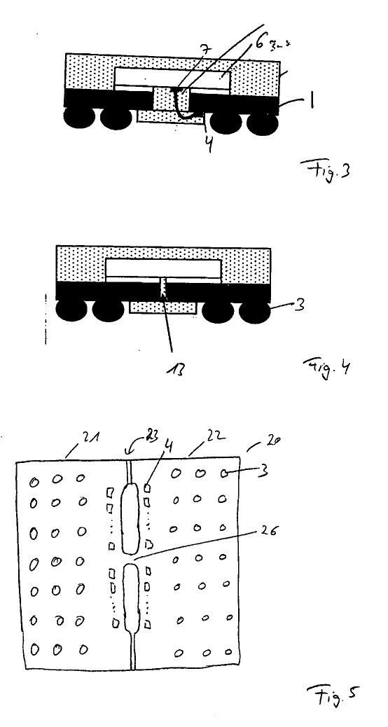

As can be seen in the cross-sectional view FIG. 3 (taken along section line A-A of FIG. 2), an integrated circuit chip 6 is arranged on the substrate 1 in such a way that second contact pads 7 of the integrated circuit chip 6 are arranged within the region of the second portion 15 of the gap 13 so that the bonding process can apply a bond wire which connects one of the second contact pads 7 of the chip and one of the first bond pad 4 on the surface of the substrate 1.

The cross-sectional view of FIG. 4 along the section line B-B of FIG. 2 shows that the width of the first portion 14 of the gap 13 can be very small, preferably in the range of 100 μm to 1000 μm. This should be sufficient to decouple the parts 11, 12 of the substrate with regard to their thermal expansion.

In the preferred embodiment, the substrate 1 is shown in two separate parts but also any other number of separated parts can be provided to realize the divided substrate. The gap 13 between every two parts 11, 12 of the substrate may comprise a bond channel or not.

According to another embodiment of the present invention, a substrate 20 is provided, as shown in FIG. 5. Same reference signs indicate elements with the same or a similar functionality. Alternative features of the embodiments described before are applicable to this embodiment. Different from the substrate 1, the embodiment of FIG. 5 shows the separate parts 21, 22 of the substrate 20 which are separated by a gap 23 having the first portion 24 and the second portion 25 as described with regard to the embodiment. Furthermore, the substrate 20 includes a bridge element 22 which mechanically connects the parts 21, 22 in such a way that an easier handling of the substrate in the fabrication process of the BGA device is possible. The bridge element 26 provides an increased mechanical stability. The bridge element is preferably formed integrally from the substrate 20 by simply removing the substrate material in the gap region.

In order to avoid that the bridge element 26 results in thermal stress between the parts 21, 22 of the substrate 20 and the integrated circuit chip to be applied thereon, the bridge element 26 is located at a neutral point which is defined by both the substrate 20 and the integrated circuit chip to be applied thereon. As the integrated circuit chip is securely fixed to the substrate 20 by means of an adhesive and/or a mechanical support element, there are regions on the substrate in which the stress due to thermal expansion is compensated in such a way that no lateral thermal expansion force occurs on the specific point which is called the neutral point of the device. The integrated circuit chip is applied on the substrate such that the neutral point of the chip opposes the bridge element so that when the integrated circuit chip is attached to the substrate, no shear force between the integrated circuit chip and the substrate 20 occurs at the neutral point, i.e. at the bridge element 26. Thereby, the provision of the bridge element 26 does not affect the thermal decoupling of the parts 21, 22 of the substrate 20 which is an effect of the present invention but provides an increased mechanical stability and an improved handling capability of the substrate.

While the foregoing is directed to embodiments of the present invention, other and further embodiments of the invention may be devised without departing from the basic scope thereof, and the scope thereof is determined by the claims that follow.

What is claimed is:

1. An integrated chip device in a package, comprising:
an integrated chip;
a substrate comprising a redistribution wiring, a contact element and a contact pad on a common surface of the substrate, wherein the contact element is in electrical contact with the contact pad; wherein the substrate formed of at least two parts each of which is attached to a respective portion of the chip to form the device; wherein a gap is formed between the two parts of the substrate to accommodate a thermal expansion of at least one of the parts of the substrate; and
a bond wire coupling the contact pad and the integrated chip through the gap.

2. The device of claim 1, wherein a further contact pad is arranged on the chip which is accessible through the gap between the parts of the substrate, the bond wire being connected to the further contact pad.

3. The device of claim 2, wherein the gap is defined by a first portion and a second portion, wherein the first portion of the gap has a first width sufficient to accommodate the thermal expansion of the parts of the substrate, and wherein the second portion of the gap has a second width sufficient to allow the bond wire to pass through the second portion onto the further contact pad.

4. The device of claim 1, wherein the chip is attached to the parts of the substrate by an adhesive.

5. The device of claim 1, wherein the chip is attached to the parts of the substrate by a connection element.

6. An integrated chip device in a package, comprising:
an integrated chip;
a substrate comprising a contact element and a contact pad on a common surface of the substrate, wherein the contact element is in electrical contact with the contact pad; wherein the substrate is formed of at least two parts each of which is attached to a respective portion of the chip to form the device; and wherein at least a first thermal expansion gap and a first bond channel are formed between the parts of the substrate, the first thermal expansion gap being dimensioned to accommodate a thermal expansion of at least one of the parts of the substrate; and
a bond wire extending through the first bond channel and connecting the contact pad and the integrated chip.

7. The device of claim 6, further comprising:
a further contact pad arranged on a surface the chip wherein the chip is mounted on the substrate such that the further bond pad is accessible through the first bond channel between the parts of the substrate.

8. The device of claim 6, further comprising:
a bridge element interconnecting the two parts of the substrate.

9. The device of claim 6, further comprising:
a bridge element interconnecting the two parts of the substrate and wherein the bridge element defines the single physical connection between the parts of the substrate.

10. The device of claim 6, wherein the first bond channel and the first thermal expansion gap have different widths defined by respective distances of the parts of the substrate from one another.

11. The device of claim 6, further comprising:
a second bond channel and a second thermal expansion gap formed by the two parts of the substrate.

12. The device of claim 6, further comprising:
a bridge element interconnecting the two parts of the substrate and wherein a second bond channel and a second thermal expansion gap are formed by the two parts of the substrate; and wherein the first bond channel and the first thermal expansion gap are formed on one side of the bridge element, and the second bond channel and the second thermal expansion gap are formed on another side of the bridge element.

13. The device of claim 6, wherein the chip is attached to the parts of the substrate by means of an adhesive.

14. The device of claim 6, wherein the chip is attached to the parts of the substrate by a connection element.

15. An integrated chip device in a package, comprising:
an integrated chip;
a substrate comprising a redistribution wiring, a contact element and a contact pad on a common surface of the substrate, wherein the contact element is in electrical contact with the contact pad; wherein the substrate is formed of at least two parts each of which is attached to a respective portion of the chip to form the device; wherein a gap is formed between the parts of the substrate to accommodate a thermal expansion of at least one of the parts of the substrate;
a bridge element interconnecting the two parts of the substrate; and
a bond wire connecting the contact pad and the integrated chip through the gap.

16. The device of claim 15, wherein the gap is defined by a first portion and a second portion, wherein the first portion of the gap has a first width sufficient to adjust the thermal expansion of at least one of the parts of the substrate, and wherein the second portion of the gap has a second width sufficient to allow bonding of the bond wire through the gap onto the contact pad.

17. The device of claim 15, wherein the bridge element is formed by the substrate.

18. The device of claim 15, wherein the bridge element is integrally formed with the parts of the substrate.

19. The device of claim 15, wherein the chip is arranged on the parts of the substrate such that a neutral point of the chip is located on the bridge element of the substrate, wherein the neutral point is defined as a point on which no lateral thermal expansion force occurs when the chip is attached to the parts of the substrate.

20. The device of claim 15, wherein the bridge element is centrally located between the parts of the substrate.

21. The device of claim 15, wherein the bridge element defines the single physical connection between the parts of the substrate.
